(19) United States
(12) Patent Application Publication
(10) Pub. No.: US 2009/0087712 A1
(43) Pub. Date: Apr. 2, 2009

(54) Fabrication method of thin film solid oxide fuel cells

(76) Inventors: Hong Huang, Centerville, OH (US); Pei-Chen Su, Stanford, CA (US); Friedrich B. Prinz, Woodside, CA (US); Rainer J. Fasching, Mill Valley, CA (US); Yuji Saito, Nerima (JP)

Correspondence Address: LUMEN PATENT FIRM, 2345 YALE STREET, SECOND FLOOR, PALO ALTO, CA, 94306, US

(21) Appl. No.: 12/229,611

(22) Filed: Aug. 22, 2008

Related U.S. Application Data
(60) Provisional application No. 60/966,420, filed on Aug. 27, 2007.

(51) Int. Cl. H01M 8/10; G03F 7/20

(52) U.S. Cl. 429/30; 430/314

(57) ABSTRACT

A silicon-based solid oxide fuel cell (SOFC) with high surface area density in a limited volume is provided. The structure consists of a corrugated nano-thin film electrolyte and a silicon supportive layer on a two-stage silicon wafer through-hole to maximize the electrochemically active surface area within a given volume. The silicon supportive layer is done by boron-etch stop technique with diffusion doping. The fabrication of two-stage wafer through hole combines deep reactive ionic etching (DRIE) and KOH wet etching of silicon for a wafer through hole containing two difference sizes. By these design and fabrication methods, the absolute electrochemically active area can be as high as five times of that of the projected area.

### CROSS-REFERENCE TO RELATED APPLICATIONS

This application is cross-referenced to and claims the benefit from U.S. Provisional Patent Application 60/966420 filed Aug. 27, 2007, which is hereby incorporated by reference. This application is a continuation-in-part application of the inventor's prior U.S. application Ser. No. 11/65546 filed Jan. 18, 2007, for Membrane Electrode Assembly In Solid Oxide Fuel Cells, which claims the benefit of U.S. Provisional Patent Application 60/760998 filed on Jan. 19, 2006, which are hereby incorporated by reference.

### FIELD OF THE INVENTION

The invention relates generally to solid oxide fuel cells. More particularly, the invention relates to increased effective surface area density for solid oxide fuel cells.

### BACKGROUND

Fuel cells are known as a clean and efficient energy transformation device. They transform chemical energy into electrical energy with water as the major product.

A Solid Oxide Fuel Cell (SOFC) is one of the major types of fuel cells, where the electrolyte is a solid-state material that generates oxygen vacancies. SOFC's utilize a range of ceramic electrolyte materials, with yttria stabilized zirconia (YSZ) being one of the more prevalent electrolyte materials, which is zirconia doped with yittria. YSZ is an oxygen ion conductor, where oxygen ions “hop” from one vacancy site to another to conduct charge thru the electrolyte from the cathode side to the anode side. The cathode and anode electrodes are made porous for gas delivery.

Due to the low oxygen ionic conductivity of solid electrolyte, traditional SOFCs need to operate at relatively high temperature (800-1000° C.). This limits the application of SOFCs to large scale, stationary applications. Operating SOFCs at low temperatures decreases the electrolyte ionic conductivity, and the power density of fuels cell is consequently sacrificed. One effective way to lower the operating temperature is to reduce the electrolyte thickness, which decreases the Ohmic loss.

A SOFC has three major losses within the fuel cell system, including the activation loss, which is the electrochemical reaction barrier, the ohmic loss due to the cell's resistance from electrode and electrolyte, and the concentration loss, which is the mass transport limit.

The overall cell voltage can be written as the thermodynamic voltage minus the above three over potentials. Among these, the ohmic loss is one major reason for the SOFC's high operating temperature. When oxygen ions hop from one vacancy site to another, high operating temperatures are needed to provide enough energy to the oxygen ion, so as to increase the ionic conductivity of the electrolyte. Thus, to lower the operating temperature of a SOFC, the resistance of the electrolyte needs to be reduced. Thinning the electrolyte to sub-micrometer thickness has been an effective way of achieving low operating temperature. The dimension of the sub-micrometer thick electrolyte is usually limited by the mechanical stability, therefore the surface area density is low and the absolute power generated is insignificant.

Accordingly, there is a need to develop a silicon-based solid oxide fuel cell (SOFC) with high surface area density in a limited volume to increase the absolute electrochemically active area.

### SUMMARY OF THE INVENTION

To address the need for a silicon-based solid oxide fuel cell (SOFC) with high surface area density in a limited volume, a SOFC electrolyte-electrode assembly is provided. The SOFC electrolyte-electrode assembly includes a substrate having a first substrate surface parallel to a second substrate surface, at least one substrate cavity that includes a substrate cavity wall, a substrate cavity base feature and a substrate cavity bottom, where the substrate cavity is disposed in the second substrate surface, a plurality of through-holes, where the through-holes are perpendicular to the substrate surfaces and span from the first substrate surface to at least the substrate cavity bottom. The SOFC electrolyte-electrode assembly further includes an electrolyte layer having a first electrolyte layer surface and a second electrolyte layer surface, where the second electrolyte layer surface is disposed on the first substrate surface and along walls of the through holes, and at least into the substrate cavity. The electrolyte layer first surface has electrolyte cavities disposed in the through-holes and at least to the substrate cavity bottom. A first electrode layer is deposited on the electrolyte first surface, where the first electrolyte layer conforms to the electrolyte cavities, and a second electrode layer is deposited on the substrate cavity walls and on the substrate cavity bottom and on the electrolyte second surface that is at least within the substrate cavity.

According to one embodiment, the first substrate surface is doped with boron. In one aspect of this embodiment, the boron doping is done by diffusion doping, where the boron doping can have a thickness up to a depth of the electrolyte cavity.

In one aspect of the invention, the substrate cavity bottom and the first electrolyte surface form a corrugated surface.

In another aspect of the invention, the substrate is silicon wafer that includes a (100) double-side silicon wafer polished to a thickness in a range from 300 μm to 1 mm.

According to another embodiment of the invention, the electrolyte cavities are arranged in a pattern of close-packed shapes. In one aspect of the current embodiment, the close-packed shapes can be circles, rectangles, squares, triangles or polygons. In one aspect of the current embodiment, the circles have diameters sizes in a range of 10 μm to 65 μm.

In a further aspect of the invention, the electrode layer can include a porous-platinum layer, a metal layer or a cermet layer.

In another aspect of the invention, the electrode layer can be fabricated by methods such as DC magnetron sputtering, evaporation, atomic layer deposition or pulse laser deposition.

In yet another aspect, the electrolyte layer is deposited using methods that can include DC magnetron sputtering, chemical vapor deposition, atomic layer deposition, or pulse laser deposition.

In a further aspect of the invention, the electrolyte layer can be yttria stabilized zirchoia, gadolinia doped ceria or any oxygen ion conductor.

According to one aspect of the invention, the electrolyte layer has a thickness in a range of 1 nm to 10 μm.

In another aspect of the invention, the substrate cavity has a width size in a range of 1 mm to 100 mm.

In one aspect, the substrate cavity has a depth in a range of 5 μm to 300 μm.

In a further aspect, the substrate cavity wall has a length size in a range of 50 μm to 250 μm.

According to yet another aspect of the invention, the substrate cavity base feature has a vertical length in a range of 10 μm to 250 μm.

In another aspect, the substrate cavity is adjacent to at least one other substrate cavity, wherein a separation distance between the substrate cavities is in a range of 50 μm to 500 μm.

In a further aspect, the substrate cavity is fabricated by a deep reactive ionic etching process and a potassium hydroxide or Tetramethylammonium hydroxide (TMAH) etching process.

According to another embodiment, the invention includes a method of making a solid oxide fuel cell electrolyte-electrode assembly. The method includes providing a silicon wafer substrate having a first surface and a second surface, growing a silicon dioxide mask on the substrate first surface, doping the substrate first surface with boron using diffusion doping, depositing a photoresist layer on the substrate first surface, removing the silicon dioxide mask, provide photolithography to make a mask of a pattern of close-packed shapes on the substrate first surface, providing direct reactive ionic etching (DRIE) in the close-packed shapes to form close-packed shaped cavities, depositing low-stress silicon nitride on the substrate first surface and on the substrate second surface using low pressure chemical vapor deposition, providing photolithography to make a silicon nitride mask of a pattern of substrate windows on the substrate second surface, providing photolithography to provide a mask-pattern on the silicon nitride mask, using DRIE to provide substrate window cavities in the substrate second surface, removing the silicon nitride layer from the substrate first surface using piranha solution, using atomic layer deposition to provide an electrolyte layer on the first substrate surface, where the electrolyte layer conforms to features of the close-packed circular cavities, providing potassium hydroxide etching on the substrate second surface and in the substrate window cavities, removing the silicon nitride layer from the substrate second surface using plasma etching, whereby exposing a bottom surface of the electrolyte layer with in the substrate window cavity, and depositing an electrode layer on the substrate first surface and an electrode layer on the substrate second surface, where the electrolyte layer is disposed between the electrolyte layers.

### BRIEF DESCRIPTION OF THE FIGURES

The objectives and advantages of the present invention will be understood by reading the following detailed description in conjunction with the drawing, in which:

FIGS. 1a-1g show the steps of a successfully fabricated nano thin film SOFC with a silicon microfabrication process.

FIGS. 2a-2d show schematic drawings of resultant window spacing from the inventor's earlier fabrication techniques the techniques according to the present invention.

FIGS. 3a-3c show schematic drawings of the silicon-based SOFC structure with high surface area density in a limited volume according to the present invention.

FIG. 4 shows a schematic cutaway view of adjacent windows of the silicon-based SOFC structure according to the present invention.

FIGS. 5a-5o show the two-stage through hole fabrication process according to the present invention.

FIGS. 6a-6c show the fabricated SOFC according to the present invention.

### DETAILED DESCRIPTION OF THE INVENTION

Although the following detailed description contains many specifics for the purposes of illustration, anyone of ordinary skill in the art will readily appreciate that many variations and alterations to the following exemplary details are within the scope of the invention. Accordingly, the following preferred embodiment of the invention is set forth without any loss of generality to, and without imposing limitations upon, the claimed invention.

Solid oxide fuel cells (SOFCs) utilize a range of ceramic electrolyte materials, with yttria stabilized zirconia (YSZ) being the most common choice. Due to the low oxygen ionic conductivity of solid electrolyte, traditional SOFCs need to operate at relatively high temperature (800-1000° C.). This limits the application of SOFCs to large scale, stationary applications. Operating SOFCs at low temperature decreases the electrolyte ionic conductivity, and consequently, the power density of fuels cell is sacrificed. One effective way to lower the operating temperature is by reducing the electrolyte thickness to decrease the Ohmic loss. This can be achieved by deposition of submicron thickness electrolyte with thin film deposition techniques, such as sputtering or atomic layer deposition (ALD). These thin film deposition techniques also facilitate employing MEMS processes to fabricate micro scale SOFC structures.

Earlier teachings by the inventors, which are incorporated by reference, include fabrication of a nano thin film SOFC using a silicon microfabrication process. A silicon wafer is used as a substrate and deposited silicon nitride provides masking layers. Thin film YSZ is deposited on the wafer's flat surface using thin film deposition techniques such as sputtering or atomic layer deposition (ALD). To obtain the thin film YSZ, the silicon is etched away with KOH solution and the silicon nitride is etched with plasma etching. On both sides of this YSZ thin film, porous Pt is deposited as electrode/catalyst.

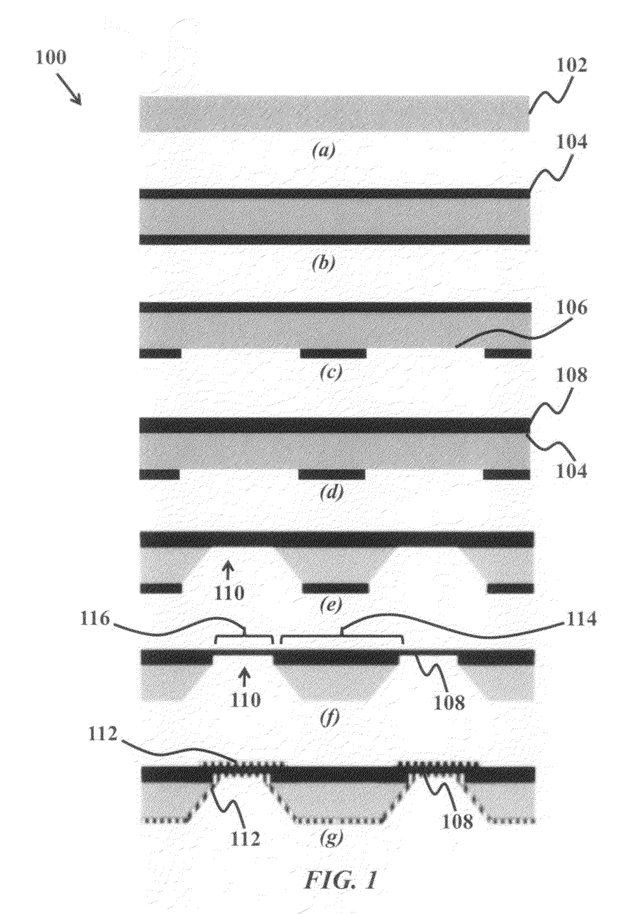

FIGS. 1a-1g show the steps of a successfully fabricated nano thin film SOFC with a silicon microfabrication process 100. FIG. 1a shows a double-side polished silicon wafer 102 was used as a substrate. FIG. 1b shows silicon nitride deposited as masking layers 104. FIG. 1c shows lithography provided etching regions 106. FIG. 1d shows a thin film of YSZ 108 deposited on the top flat surface 104 with thin film deposition techniques such as sputtering or atomic layer deposition, or ALD. As shown in FIGS. 1e and 1f a thin film of YSZ 108 is suspended across the windows 110 where, as shown in FIG. 1f, the silicon 102 is etched away with KOH solution and the silicon nitride mask 104/106 with plasma etching. FIG. 1g shows porous Pt as electrode/catalyst 112 deposited on both sides of this YSZ thin film 108.

The fuel cell's low operating temperature has reported power densities as high as 400 mW/cm² at 400 degrees centigrade. Although such power densities from a single MEMS fuel cell at low temperatures are high, the absolute power output is too low for practical use, where one of the shortcomings of this structure is that there is a very limited effective area density

The planar micro SOFC gives high power density, though the absolute power delivered by this device is too small. The reason for the small power delivery of this SOFC is the low surface area density. After the KOH etching process as shown in the transition from FIGS. 1e and 1f, a large spacing 114 exits between each window 110 due to the crystallinity of (100) silicon wafers. For a silicon wafer with thickness of 350 μm, the spacing between each window is as large as 500 μm. If the window size on the silicon nitride mask 104/106 is designed as 600 μm, after KOH etching the window size on top 116 is only 100 μm. This resulted in a tiny surface area density of only (100 μm)²/(600 μm)²=2.8%. Thus, a need exists to keep the membrane 108 thickness small but reduce the spacing between the windows 110; this is accomplished by using a two-stage wafer through-hole etching process, according to the current invention.

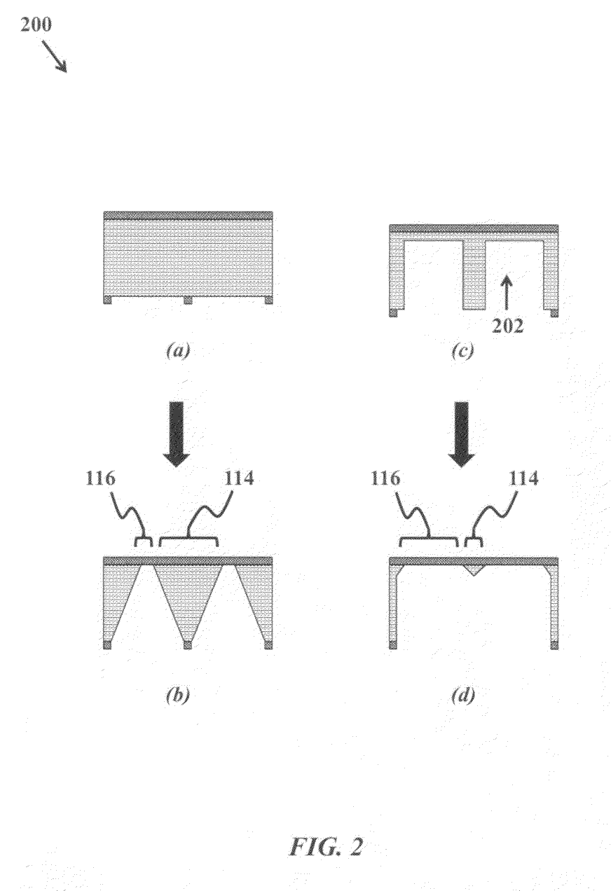

FIGS. 2a-2d show schematic drawings of resultant window spacing 200 from the inventor's earlier fabrication techniques and according to the current invention, where FIGS. 2a and 2b show the usable surface area from a KOH etching process alone, and FIGS. 2c and 2d show the larger usable surface area from a two-stage wafer through hole etching, according to the current invention.

As will be shown below, to effectively increase the surface area density in a limited volume, the current invention provides a solid oxide fuel cell electrolyte-electrode assembly, which includes a corrugated nano thin film YSZ membrane structure. According to one embodiment, the YSZ is deposited by atomic layer deposition (ALD) on a 4″ silicon substrate that is pre-patterned with 10-40 μm deep circular trenches. The YSZ replicates the pre-patterned surface profile and forms a corrugated electrolyte membrane after removal of the silicon substrate. The deeper the trench is, the higher the resulting surface area density. Based on the corrugated thin film SOFC developed, two new fabrication methods are provided to reinforce the corrugated electrolyte membrane and to further increase the usable wafer surface area. One is based on a heavy boron-doped silicon-supporting layer, and the other comprises a two-stage wafer through hole.

When silicon is doped with boron concentrations higher than 10₁₉/cm3, the etching rate in KOH of silicon decreases significantly. One aspect of the current invention uses boron doping in silicon wafers as an etch stop in KOH etching. By utilizing this boron etch stop technique, a few micrometer thick of silicon can be left after KOH etching to act as a supporting layer for the freestanding corrugated YSZ membrane when fabricated by the methods of the current invention. This provides a mechanical reinforcement of the corrugated thin film YSZ membrane and allows deeper corrugation.

The two-stage wafer though hole enables the fabrication of a through wafer hole comprising two different sizes. The purpose of this method is to increase the usable wafer surface area while keep the freestanding membrane small. In a through-wafer etching with KOH solution, the crystallinity of (100) silicon wafer inevitably limits the opening on the top surface. The two-stage wafer through hole etching process combines a direct reactive ionic etching (DRIE) and a KOH etching. The anisotropic DRIE etching first etches through a portion of the wafer thickness before reaching the pattern on the other side. The DRIE etching creates a stage II window 202. The wafer through hole is then completed by KOH etching of (100) surfaces. The enhancement in surface area of the two-stage wafer though hole method, relative to KOH etching, is illustrated in FIG. 2(d). The deeper the DRIE etching, the smaller the spacing between stage-II windows 202 and the large the usable surface area 116. The improvement in percentage of usable surface area is much more significant for smaller stage-II holes 202. By the combination of the two strategies (DRIE etching and KOH etching), the ultimate structure of the high surface area density fuel cell is created.

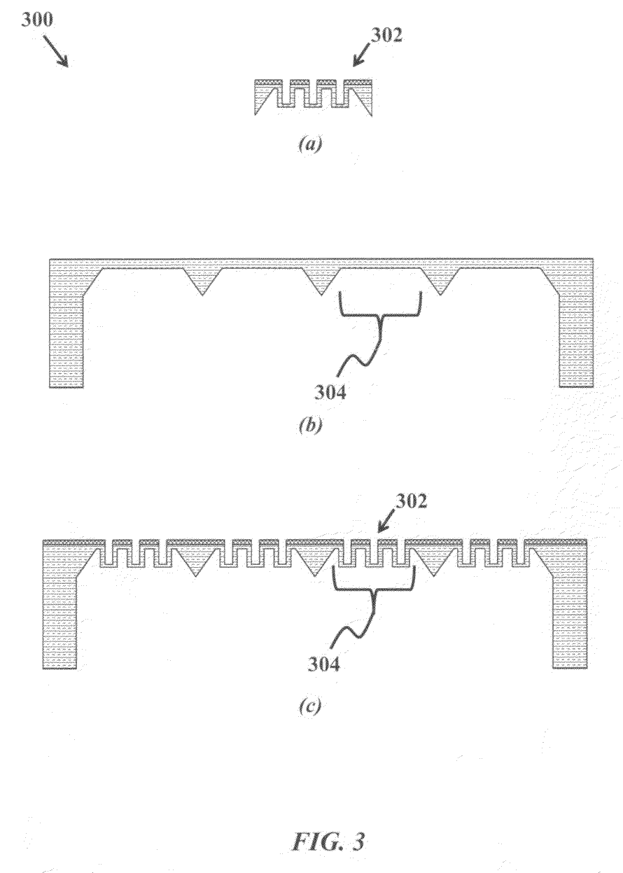

FIGS. 3a-3c show schematic drawings of the silicon-based SOFC structure 300 with high surface area density in a limited volume. Here, FIG. 3a shows a general electrolyte/electrode assembly 302 spanning a window 304 (see FIG. 3b) provided by the two-step process according to the current invention. FIG. 3c shows multiple adjacent windows 304 with the electrolyte/electrode assembly 302 fabricated therein.

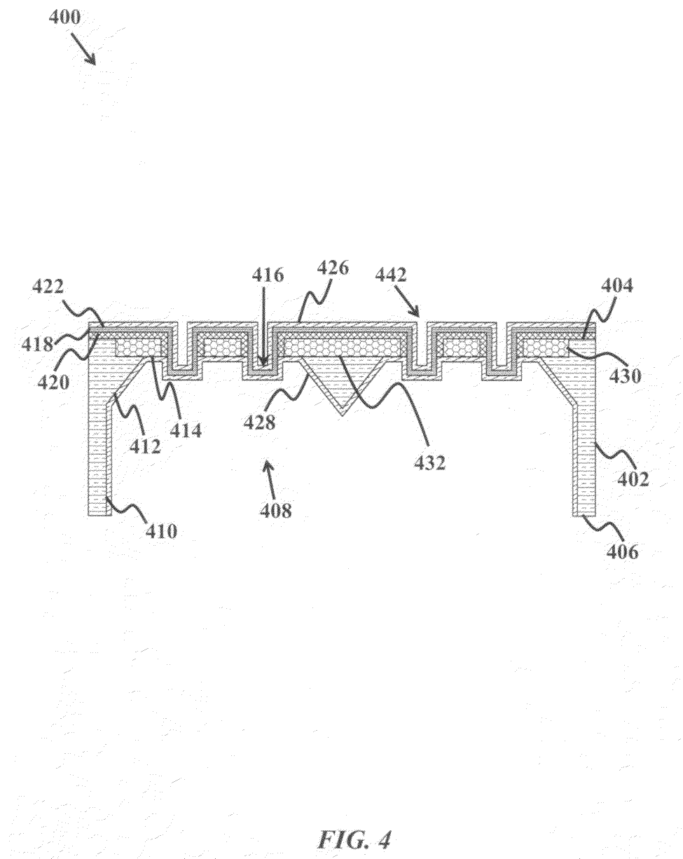

FIG. 4 shows a schematic cutaway view of adjacent windows of the silicon-based SOFC structure 400. The SOFC 400 includes a substrate 402 having a first substrate surface 404 parallel to a second substrate surface 406, at least one substrate cavity 408 that includes a substrate cavity wall 410, a substrate cavity base feature 412 and a substrate cavity bottom 414, where the substrate cavity 408 is disposed in the second substrate surface 406, a plurality of through-holes 416, where the through-holes 416 are perpendicular to the substrate surfaces (404/406) and span at least from the first substrate surface 404 to the substrate cavity bottom 414. The substrate cavity 408 can have a width size in a range of 1 mm to 100 mm and a depth size in a range of 5 μm to 300 μm, the cavity walls 410 can have a length size in a range of 50 μm to 250 μm, and the base feature 412 can have a vertical length in a range of 10 μm to 250 μm. The SOFC electrolyte-electrode assembly 400 further includes an electrolyte layer 418 having a first electrolyte layer surface 420 and a second electrolyte layer surface 422, where the second electrolyte layer surface 422 is disposed on the first substrate surface 402 and along walls of the through holes 416, and at least into the substrate cavity 408. The electrolyte layer first surface 420 has electrolyte cavities 424 disposed in the through-holes 416 and at least to the substrate cavity bottom 414. A first electrode layer 426 is deposited on the electrolyte first surface 422, where the first electrolyte layer 426 conforms to the electrolyte cavities 424, and a second electrode layer 428 is deposited on the substrate cavity walls 410, cavity base feature 412 and on the substrate cavity bottom 414 and on the electrolyte second surface 420 that is at least within the substrate cavity 408. The addition of boron etch stop supporting layer 430 helps to maintain the strength of the corrugated thin film and allows deeper thin film corrugation. FIG. 4 further shows an inverted triangular shape substrate cavity separator 432, where the base of the triangle-shape defines a separation distance between the substrate cavity 408 and the separation distance can have a range of 50 μm to 500 μm. The thickness of the electrode layer 418 can have a thickness in a range of 1 nm to 10 μm. Further, an example for considering a minimum thickness of the electrolyte layer 418, where using atomic layer deposition allows individual material layers to be deposited, a lower limit for the thickness of the electrolyte layer 418 can be around seven-zirchonia layers with a single yttria layer to provide an optimization between ion conduction and lowered operating temperature. Other examples of deposition methods for the electrolyte layer can include DC magnetron sputterning, evaporation, and pulse laser deposition.

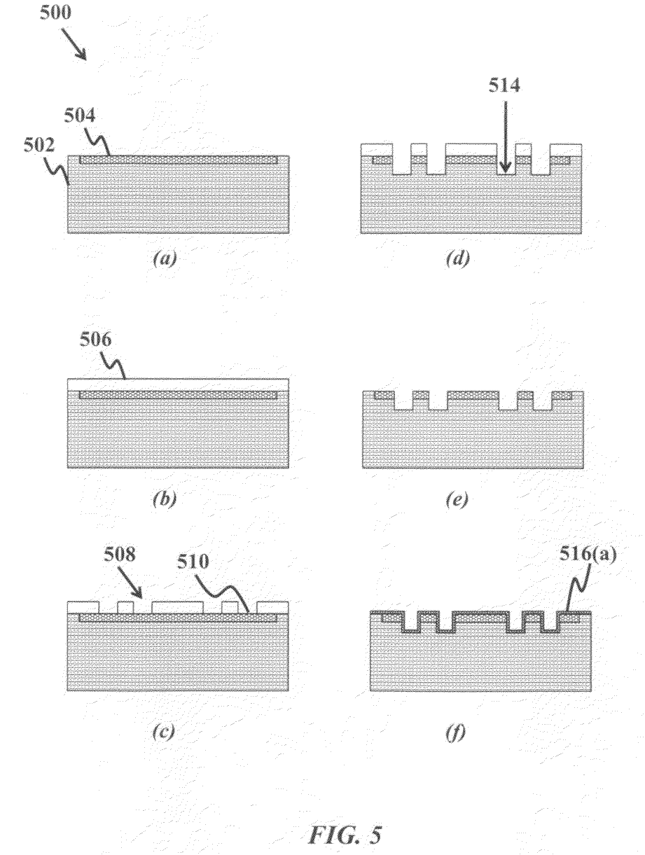

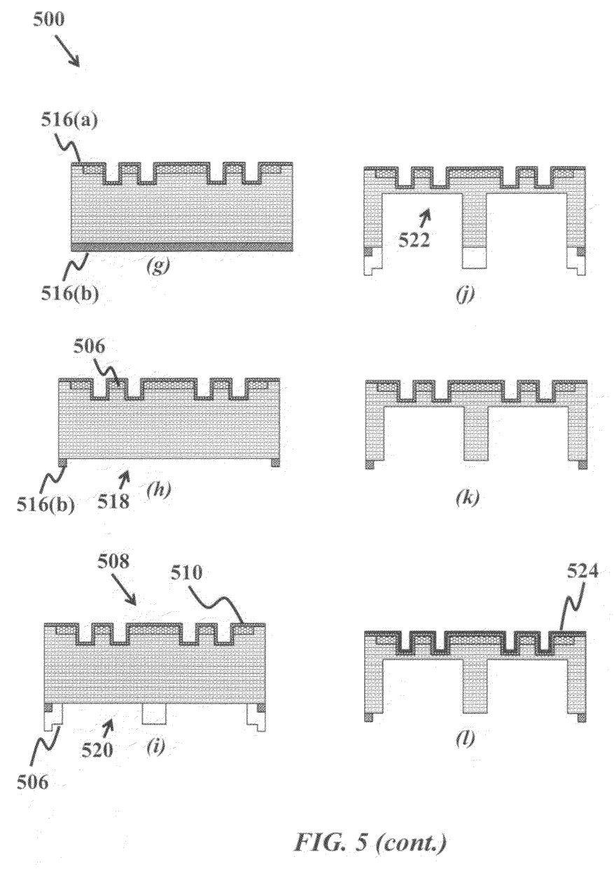

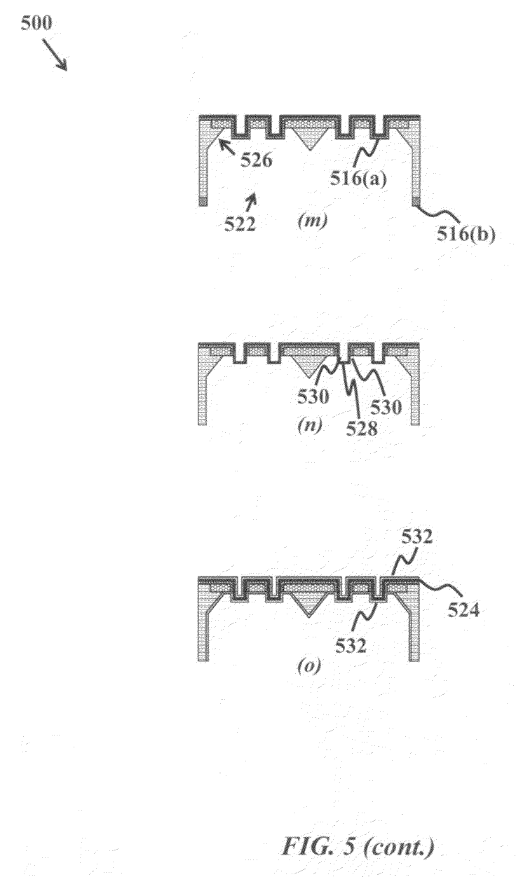

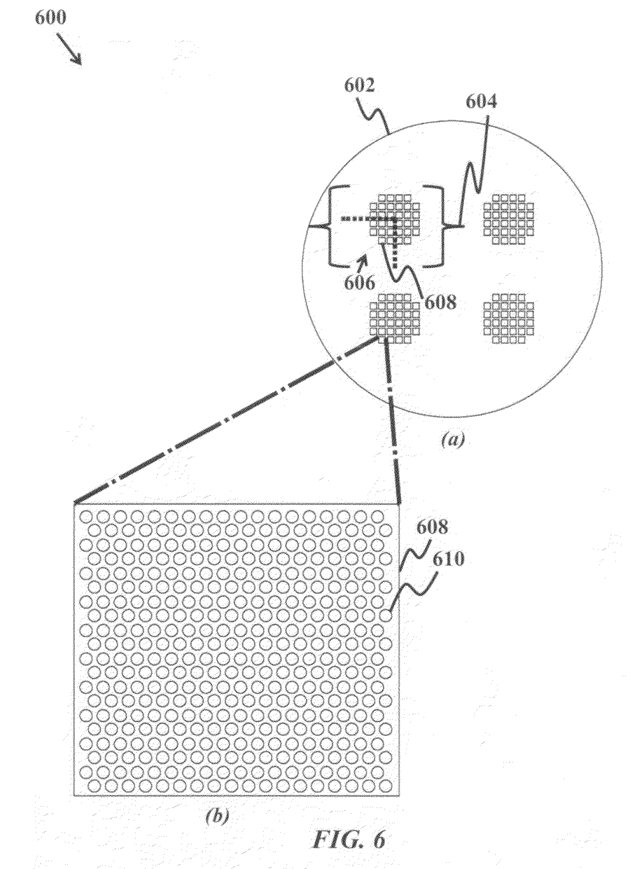

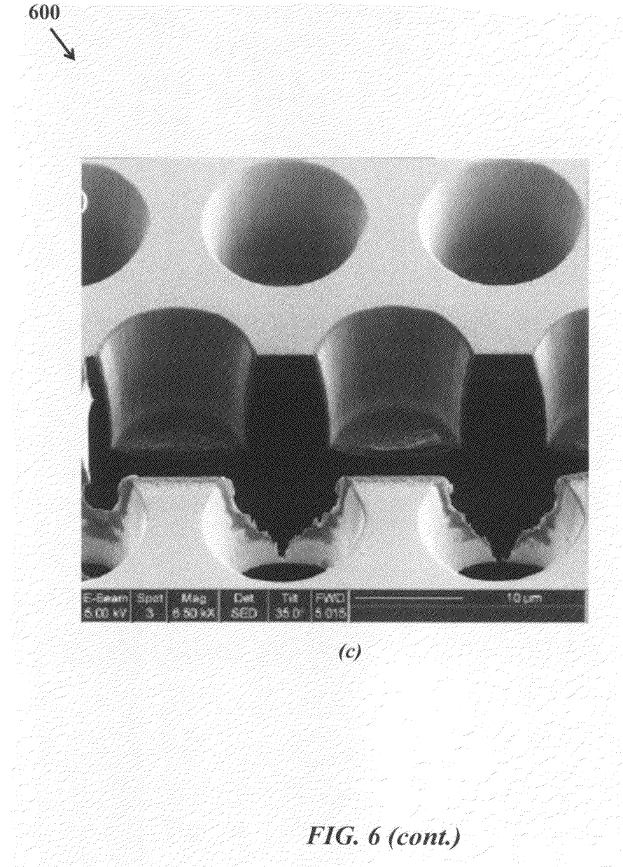

FIGS. 5a-5o show the two-stage through-hole fabrication process 500. FIG. 5a shows a cutaway side view of a four-inch silicon wafer 502 used as the substrate for the SOFC structure 400 of FIG. 4. The wafer 502 in this exemplary embodiment is p-type (100) double side polished with 350-400 μm in thickness. One surface is first doped with boron 504 by diffusion doping at 1100° C. for 6 hours, with 1 μm of silicon dioxide as doping mask (not shown). FIG. 5b shows a 1.6 μm thick of photoresist 506 (3612 positive resist from Shipley Co.) coated on the boron-doped side. FIG. 5c shows photolithography 508 being used to make a mask 510 with circles 512 arranged in close-packed layout (see FIG. 6b) to maximize the number of circles 512 in the limited surface area. It should be apparent that other shapes could be used such as rectangles, squares, triangles or polygons, for example. Circle sizes can be from 10 μm to 65 μm. FIG. 5d shows the circles are etched with DRIE to make cup-shaped trenches 514. FIG. 5e shows photoresist 506 layer removed. FIGS. 5f and 5g show 100 nm of low-stress silicon nitride 516 deposited by low-pressure chemical vapor deposition (LPCVD) on both sides of the wafer 502, where the silicon nitride 516(a) conforms to the cup-shaped trenches 514 on the top surface. FIG. 5h shows the silicon nitride 516(b) then being patterned with photolithography to form the stage-I window mask for KOH etching. The window sizes are from 10 mm to 60 mm. FIG. 5i shows a 7 μm thick photoresist layer 506 coated on top of the silicon nitride 516(b) stage-I mask and patterned with photolithography to make small window mask 520 for DRIE. The edge of the outer most small windows have a 50˜200 μm of distance to the silicon nitride mask edge. This is to prevent from a concaved shape of (111) surface after KOH etching. FIG. 5j shows the wafer 502 being etched with DRIE for 50 μm to 250 μm in depth for the first step 522 of wafer through hole. After removing the photoresist (see FIG. 5k) in piranha solution, FIG. 5l shows the YSZ thin film electrolyte 524 with thickness of 50-150 nm is deposited on the silicon nitride 516(a) in the cup-shaped trenches 514 by ALD technique. The deposited YSZ 524 replicates the pre-patterned surface contour of the circular trenches 514. To complete the two-stage wafer-through hole, the opened Si windows 522 are etched 526 in 10% KOH solution at 60° C., as shown in FIG. 5m. The etching 526 will stop at the nitride layer 516(a) and slow down at the heavily boron doped silicon layer 504. The silicon nitride layer 516(a) adhering to the electrolyte 524 is then removed by SF₆ plasma etching, as shown in FIG. 5n. The active surface areas for electrochemical reaction are the YSZ cups bottom 528 and partial cup sidewalls 530. Finally, FIG. 5o shows porous platinum electrode/catalyst films 532 (cathode and anode) deposited on both sides of YSZ 524 with DC magnetron sputtering.

FIGS. 6a-6c show the fabricated SOFC 600, where FIG. 6c shows a photo image of the fabricated SOFC 600. In FIG. 6a, a 4-inch silicon wafer 602 with four SOFC chips 604 are presented. Each chip 604 contains four stage-I windows 606, with eight stage-II windows 608 inside each of them. The sizes of the stage-II windows 608 fabricated are from 2 mm×2 mm to 6 mm×6 mm. Each stage-II window 608 contains a sheer number of YSZ “cups” 610 (see FIG. 6b) from several thousands to several hundred thousands depending on the window 608 size. The spacing between stage-II windows 608 are from 200 μm to 410 μm, depending on the design and on the depth of etching in FIG. 5j. This spacing is larger than 550 μm if only KOH etching is used, so the reduction of the spacing is obvious and the increasing in usable wafer surface area is particularly significant for smaller sizes of windows. FIG. 6c shows an image of a cross-section view of the corrugated membrane supported by the boron-doped silicon layer. For the image shown here, the cup depth is 10 μm, and the supporting layer is about 3 μm thick. The suspending porous-Pt/YSZ/porous-Pt membrane is 120 nm/80 nm/120 nm, respectively.

The nano thin film SOFCs is fabricated by using MEMS fabrication methods, including boron-etch stop technique and two-stage wafer through hole. The boron-etch stop provides a stable support for the YSZ thin film electrolyte and allows 3 mm×3 mm to 6 mm×3 mm of free-standing membranes hanging over the through-wafer window. The two-stage wafer through-hole technique reduces the spacing between etch window and increases the usable wafer surface area.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example the doped boron supportive layer can be grown by growing epitaxial silicon with in-situ boron doping. Further, the shapes of the through-holes are not limited to circular, rectangular, squares, triangles or polygons.

All such variations are considered to be within the scope and spirit of the present invention as defined by the following claims and their legal equivalents.

What is claimed:

1. A solid oxide fuel cell electrolyte-electrode assembly comprising:
a. a substrate comprising a first substrate surface parallel to a second substrate surface;
b. at least one substrate cavity comprising a substrate cavity wall, a substrate cavity base feature and a substrate cavity bottom, wherein said substrate cavity is disposed in said second substrate surface;
c. a plurality of through-holes, wherein said through-holes are perpendicular to said substrate surfaces and span from said first substrate surface to at least said substrate cavity bottom;
d. an electrolyte layer comprising a first electrolyte layer surface and a second electrolyte layer surface, wherein said second electrolyte layer surface is disposed on said first substrate surface and along walls of said through holes and at least into said substrate cavity, wherein said electrolyte layer first surface comprises electrolyte cavities disposed in said through-holes and at least to said substrate cavity bottom;
e. a first electrode layer, wherein sad first electrolyte layer is deposited on said electrolyte first surface, wherein said first electrolyte layer conforms to said electrolyte cavities; and
f. a second electrode layer, wherein said second electrode layer is deposited on said substrate cavity walls and said base feature and on said substrate cavity bottom and on said electrolyte second surface at least within said substrate cavity.

2. The electrolyte-electrode assembly of claim 1, wherein said first substrate surface is doped with boron.

3. The electrolyte-electrode assembly of claim 2, wherein said boron doping is done by diffusion doping, wherein said boron doping has a thickness from zero up to a depth of said electrolyte cavity.

4. The electrolyte-electrode assembly of claim 1, wherein said substrate cavity bottom and said first electrolyte surface form a corrugated surface.

5. The electrolyte-electrode assembly of claim 1, wherein said substrate is silicon wafer comprises a (100) double-side silicon wafer polished to a thickness in a range from 300 μm to 1 mm.

6. The electrolyte-electrode assembly of claim 1, wherein said electrolyte cavities are arranged in a pattern of close-packed shapes.

7. The electrolyte-electrode assembly of claim 6, wherein said shapes are selected from a group consisting of circles, rectangles, squares, triangles and polygons.

8. The electrolyte-electrode assembly of claim 7, wherein said shapes have diameters sizes in a range of 10 μm to 65 μm.

9. The electrolyte-electrode assembly of claim 1, wherein said electrode layer is selected from a group consisting of a porous-platinum layer, a metal layer and a cermet layer.

10. The electrolyte-electrode assembly of claim 1, wherein said electrode layer is fabricated by methods selected from the group consisting of DC magnetron sputtering, evaporation, atomic layer deposition and pulse laser deposition.

11. The electrolyte-electrode assembly of claim 1, wherein said electrolyte layer is deposited using methods selected from the group consisting of DC magnetron sputtering, chemical vapor deposition, atomic layer deposition, and pulse laser deposition.

12. The electrolyte-electrode assembly of claim 1, wherein said electrolyte layer is selected from a group consisting of yttria stabilized zirchoia, gadolinia doped ceria and any oxygen ion conductor.

13. The electrolyte-electrode assembly of claim 1, wherein said electrolyte layer has a thickness in a range of 1 nm to 10 μm.

14. The electrolyte-electrode assembly of claim 1, wherein said substrate cavity has a width size in a range of 1 mm to 100 mm.

15. The electrolyte-electrode assembly of claim 1, wherein said substrate cavity has a depth in a range of 5 μm to 300 μm.

16. The electrolyte-electrode assembly of claim 1, wherein said substrate cavity wall has a length size in a range of 50 μm to 250 μm.

17. The electrolyte-electrode assembly of claim 1, wherein said substrate cavity base feature has a vertical length in a range of 10 μm to 250 μm.

18. The electrolyte-electrode assembly of claim 1, wherein said substrate cavity is adjacent to another at least one said substrate cavity, wherein a separation distance between said substrate cavities is in a range of 50 μm to 500 μm.

19. The electrolyte-electrode assembly of claim 1, wherein said substrate cavity is fabricated by a deep reactive ionic etching process and a potassium hydroxide or Tetramethylammonium hydroxide (TMAH) etching process.

20. A method of making a solid oxide fuel cell electrolyte-electrode assembly comprising;
a. providing a silicon wafer substrate, wherein said substrate comprises a first surface and a second surface;
b. growing a silicon dioxide mask on said substrate first surface;
c. doping said substrate first surface with boron using diffusion doping;
d. depositing a photoresist layer on said substrate first surface;
e. removing said silicon dioxide mask;
f. providing photolithography to make a mask of a pattern of close-packed shapes on said substrate first surface;
g. providing direct reactive ionic etching (DRIE) in said close-packed shapes to form close-packed shaped cavities;
h. depositing low-stress silicon nitride on said substrate first surface and on said substrate second surface using low pressure chemical vapor deposition;
i. providing photolithography to make a silicon nitride mask of a pattern of substrate windows on said substrate second surface;
j. providing photolithography to provide a mask-pattern on said silicon nitride mask;
k. using DRIE to provide substrate window cavities in said substrate second surface;
l. removing said silicon nitride layer from said substrate first surface using piranha solution;
m. using atomic layer deposition to provide an electrolyte layer on said first substrate surface, wherein said electrolyte layer conforms to features of said close-packed circular cavities;
n. providing potassium hydroxide or tetramethylammonium hydroxide (TMAH) etching on said substrate second surface and in said substrate window cavities;
o. removing said silicon nitride layer from said substrate second surface using plasma etching, wherein exposing a bottom surface of said electrolyte layer with in said substrate window cavity; and
p. depositing an electrode layer on said substrate first surface and an electrode layer on said substrate second surface, wherein said electrolyte layer is disposed between said electrolyte layers.
